(19) United States
(12) Patent Application Publication
(10) Pub. No.: US 2024/0147781 A1
(43) Pub. Date: May 2, 2024

(54) DISPLAY DEVICE

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Yuanchun Wu, Shenzhen, Guangdong (CN); Ying Yan, Shenzhen, Guangdong (CN); Weiran Cao, Shenzhen, Guangdong (CN); Shijian Qin, Shenzhen, Guangdong (CN); Hui Huang, Shenzhen, Guangdong (CN)

(73) Assignee: SHENZHEN CHINA STAR OPTOELECTRONICS SEMICONDUCTOR DISPLAY TECHNOLOGY CO., LTD., Shenzhen, Guangdong (CN)

(21) Appl. No.: 17/754,999

(22) PCT Filed: Mar. 11, 2022
(86) PCT No.: PCT/CN2022/080456

§ 371 Date: Sep. 7, 2023

(30) Foreign Application Priority Data
Mar. 2, 2022 (CN) 202210198235.0

(51) Int. Cl. H10K 59/124; H10K 59/126

(52) U.S. Cl. CPC H10K 59/124; H10K 59/126

(57) ABSTRACT

An embodiment of the present application provides a display device including a substrate, a driving circuit layer, a light emitting device layer, and a color filter unit that are disposed in a stacked manner; at least one of the light emitting device layer or the color filter unit is provided with a buffer groove in which a plurality of elastic particles are provided. When the display device is subject to an impact, a plurality of elastic particles in the buffer groove are compressed and deformed after being pressed, so as to play a role of buffering and effectively improve the impact resistance of the display device.

### FIELD OF INVENTION

The present application relates to a display field, and in particular, to a display device.

### BACKGROUND OF INVENTION

The organic light emitting display has many advantages, such as self-emission, low driving voltage, high luminous efficiency, short response time, high clarity and contrast, about 180 degrees of viewing angle, wide operating temperature range, flexible display and large-area full-color display, etc., and is recognized as the most promising display device in the industry.

With the maturity of the flexible organic light emitting diode display device technology, the flexible organic light emitting diode display device may be mass produced and provides a reliable basis for the production of a folding screen. In the process of manufacturing the foldable organic light emitting diode display device, in order to make the product thin and light and to facilitate bending, the thickness of various films is reduced as much as possible, but the thinning of the film may result in a reduction in impact resistance of the product, and the product will be liable to be damaged.

Therefore, after the production of the organic light emitting diode display device is completed, a series of display panel reliability tests are usually performed, and a falling sphere test is usually used to test the impact resistance of the screen. A display defect such as a black spot, a bright spot, a color spot, or a failure to display full color occurs when the display panel is hit by a falling sphere, and is mainly a damage caused when the display panel is subject to a frontal impact.

Therefore, there is an urgent need for a technical solution capable of solving a problem of low impact resistance of the organic light emitting diode display device.

### SUMMARY OF INVENTION

### Technical Problems

Embodiments of the present application provide a display device, which can solve a technical problem of low impact resistance of an organic light emitting diode display device.

### Technical Solutions

An embodiment of the present application provides a display device including:
a substrate;
a driving circuit layer disposed on the substrate;
a light emitting device layer disposed on the driving circuit layer, wherein the light emitting device layer is electrically connected to the driving circuit layer; and a color filter unit covering the light emitting device layer;
wherein at least one of the light emitting device layer or the color filter unit is provided with a buffer groove, and a plurality of elastic particles are provided in the buffer groove.

Optionally, in some embodiments of the present application, a filling amount of the elastic particles in the buffer groove is less than 95%.

Optionally, in some embodiments of the present application, the display device has a display area, the display area includes a light shielding area and a plurality of sub-pixel areas. The light shielding area divides the display area into the plurality of sub-pixel areas, and both the buffer groove and the plurality of elastic particles are disposed corresponding to the light shielding area.

Optionally, in some embodiments of the present application, the driving circuit layer includes a light shielding electrode, a buffer layer, an active layer, a gate insulating layer, a gate, an interlayer dielectric layer, a source, a drain and an interlayer insulating layer, the light shielding electrode is disposed on the substrate, the buffer layer covers the substrate and the light shielding electrode, the active layer is disposed on the buffer layer and corresponds to the light shielding electrode, the gate insulating layer is disposed on the active layer, the gate is disposed on the gate insulating layer, the interlayer dielectric layer covers the buffer layer, the active layer and the gate, the source and the drain are spaced apart from each other on the interlayer dielectric layer, the source is electrically connected to one end of the active layer, the drain is electrically connected to another end of the active layer, and the interlayer insulating layer covers the interlayer dielectric layer, the source and the drain.

Optionally, in some embodiments of the present application, the light emitting device layer includes a first electrode, a pixel defining layer, a light emitting function layer, and a second electrode, the first electrode is provided on the driving circuit layer;
the pixel defining layer covers the first electrode and the driving circuit layer, the pixel defining layer is provided with a pixel opening, and the pixel opening exposes the first electrode;
the light emitting function layer is disposed on the first electrode in the pixel opening;
the second electrode covers the light emitting function layer and the pixel defining layer; and
the buffer groove includes a first buffer groove disposed in the pixel defining layer, and the plurality of elastic particles are disposed in the first buffer groove.

Optionally, in some embodiments of the present application, the display device further includes a first force-bearing layer disposed on the pixel defining layer, the first force-bearing layer is spaced apart from the second electrode, and the first force-bearing layer covers the elastic particles in the first buffer groove.

Optionally, in some embodiments of the present application, the display device further includes an encapsulation layer, the encapsulation layer covers the light emitting device layer and the first force-bearing layer, and the encapsulation layer is located on a side of the color filter unit near the light emitting device layer.

Optionally, in some embodiments of the present application, the encapsulation layer includes a first inorganic layer, an organic layer, and a second inorganic layer, the first inorganic layer covers the light emitting device layer and the first force-bearing layer, the organic layer covers the first inorganic layer, and the second inorganic layer covers the organic layer.

Optionally, in some embodiments of the present application, the first force-bearing layer includes a plurality of first lines extending in a first direction and a plurality of second lines extending in a second direction, the first lines intersect the second lines, and the first buffer groove is disposed corresponding to intersections between the first lines and the second lines.

Optionally, in some embodiments of the present application, the driving circuit layer includes a first touch electrode, and the first buffer groove exposes the first touch electrode;
both the first force-bearing layer and the elastic particles have an electrical conductivity, and the first force-bearing layer is electrically connected to the first touch electrode through the elastic particles in the first buffer groove.

Optionally, in some embodiments of the present application, the driving circuit layer further includes an interlayer insulating layer covering the first touch electrode;
the buffer groove further includes a second buffer groove provided in the interlayer insulating layer, the second buffer groove exposes the first touch electrode;
the second buffer groove is disposed corresponding to the first buffer groove, and a plurality of the elastic particles are disposed in the second buffer groove; and
the first force-bearing layer is electrically connected to the first touch electrode through the elastic particles in the first buffer groove and the elastic particles in the second buffer groove.

Optionally, in some embodiments of the present application, the interlayer insulating layer includes a first insulating layer and a second insulating layer, the first insulating layer covers the first touch electrode, the second insulating layer covers the first insulating layer, each of the first insulating layer and the second insulating layer is provided with the second buffer groove, the second buffer groove of the first insulating layer communicates with the second buffer groove of the second insulating layer, and the second buffer groove of the second insulating layer communicates with the first buffer groove.

Optionally, in some embodiments of the present application, the color filter unit includes a package cover plate and a light shielding layer, the light shielding layer is disposed on a side of the package cover plate near the light emitting device layer, the buffer groove includes a third buffer groove disposed on the light shielding layer, and the plurality of elastic particles are disposed in the third buffer groove.

Optionally, in some embodiments of the present application, the light shielding layer includes a first light shielding strip extending in a first direction and a second light shielding strip extending in a second direction, the first light shielding strip intersects the second light shielding strip, and each of the first light shielding strip and the second light shielding strip is provided with the third buffer groove.

Optionally, in some embodiments of the present application, a plurality of first light shielding strips and a plurality of second light shielding strips are combined to form a plurality of grooves, and a corresponding color filter is provided in each of the plurality of grooves.

Optionally, in some embodiments of the present application, the display device further includes a second force-bearing layer disposed on a side of the light shielding layer near the light emitting device layer, the second force-bearing layer covers the elastic particles in the third buffer groove.

Optionally, in some embodiments of the present application, a material of the second force-bearing layer is a polymer gel, and the polymer gel fills gaps between the adjacent elastic particles in the third buffer groove.

Optionally, in some embodiments of the present application, the display device further includes a second touch electrode disposed between the package cover plate and the light shielding layer, and the third buffer groove exposes the second touch electrode;
both the second force-bearing layer and the elastic particles have an electrical conductivity, and the second force-bearing layer is electrically connected to the second touch electrode through the elastic particles in the third buffer groove.

Optionally, in some embodiments of the present application, the elastic particles are selected from at least one of silver nanoparticles, zinc oxide particles, tin oxide particles, titanium dioxide particles, gold particles, aluminum particles, or carbon nanotube particles.

Optionally, in some embodiments of the present application, a particle size of the elastic particles ranges from 5 nanometers to 100 nanometers.

### Advantageous Effects

An embodiment of the present application provides a display device, a buffer groove is provided in at least one of a light emitting device layer or a color filter unit, and a plurality of elastic particles are filled in the buffer groove. When the display device is subject to an impact, the plurality of elastic particles in the buffer groove are compressed and deformed after being pressed, so as to play a role of buffering and effectively improve the impact resistance of the display device.

### DESCRIPTION OF DRAWINGS

In order to more clearly explain the technical solutions in the embodiments of the present application, the drawings required for describing the embodiments will be described below. It is apparent that the drawings in the description below are merely some embodiments of the present application, and those skilled in the art may derive other drawings from these drawings without creative efforts.

FIG. 1 is a schematic cross-sectional view of a first display device according to an embodiment of the present application;

FIG. 2 is a schematic cross-sectional view of a second display device according to an embodiment of the present application;

FIG. 3 is a schematic cross-sectional view of a third display device according to an embodiment of the present application;

FIG. 4 is a schematic top view of a light emitting device layer according to an embodiment of the present application;

FIG. 5 is a schematic cross-sectional view of a fourth display device according to an embodiment of the present application;

FIG. 6 is a schematic cross-sectional view of a fifth display device according to an embodiment of the present application;

FIG. 7 is a schematic cross-sectional view of a first type of package cover plate according to an embodiment of the present application;

FIG. 8 is a schematic top view of a package substrate provided with a light shielding layer, a color filter and elastic particles according to an embodiment of the present application;

FIG. 9 is a schematic cross-sectional view of a second type of package cover plate according to an embodiment of the present application;

FIG. 10 is a schematic cross-sectional view of a sixth display device according to an embodiment of the present application;

FIG. 11 is a schematic top view of a package substrate provided with a light shielding layer, a color filter, elastic particles, and a second force-bearing layer according to an embodiment of the present application.

### DETAILED DESCRIPTION OF EMBODIMENTS

Technical solutions in embodiments of the present application will be clearly and completely described below in conjunction with drawings in the embodiments of the present application. Obviously, the described embodiments are only a part of embodiments of the present application, rather than all the embodiments. Based on the embodiments in the present application, all other embodiments obtained by those skilled in the art without creative work fall within the protection scope of the present application. In addition, it should be understood that the specific implementations described here are only used to illustrate and explain the present disclosure, and are not used to limit the present disclosure. In the present disclosure, unless otherwise stated, directional words used such as “upper” and “lower” generally refer to the upper and lower directions of the device in actual use or working state, and specifically refer to the drawing directions in the drawings; and “inner” and “outer” refer to the outline of the device.

Embodiments of the present application provide a display device. Detailed description will be given below. It should be noted that the order of description of the following embodiments is not intended to limit the preferred order of the embodiments.

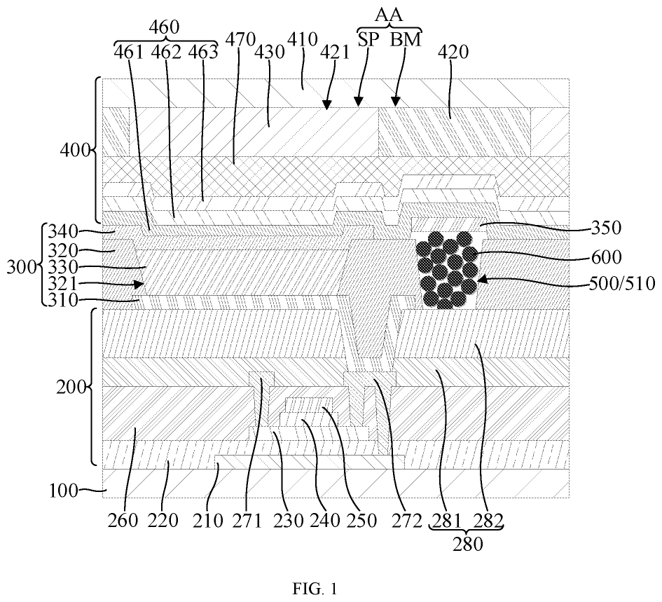

Referring to FIG. 1 to FIG. 3, an embodiment of the present application provides a display device, including a substrate 100, a driving circuit layer 200, a light emitting device layer 300, and a color filter unit 400. The driving circuit layer 200 is disposed on the substrate 100, the light emitting device layer 300 is disposed on the driving circuit layer 200, the light emitting device layer 300 is electrically connected to the driving circuit layer 200, and the color filter unit 400 covers the light emitting device layer 300. At least one of the light emitting device layer 300 or the color filter unit 400 is provided with a buffer groove 500 in which a plurality of elastic particles 600 are provided.

As shown in FIG. 1, the light emitting device layer 300 is provided with a buffer groove 500, and the buffer groove 500 of the light emitting device layer 300 is provided with a plurality of elastic particles 600. When the display device is subject to an impact, the plurality of elastic particles 600 in the buffer groove 500 are compressed and deformed after being pressed, so as to play a role of buffering and effectively improve the impact resistance of the display device. When the impact force is exhausted, the plurality of elastic particles 600 in the buffer groove 500 return to the initial state.

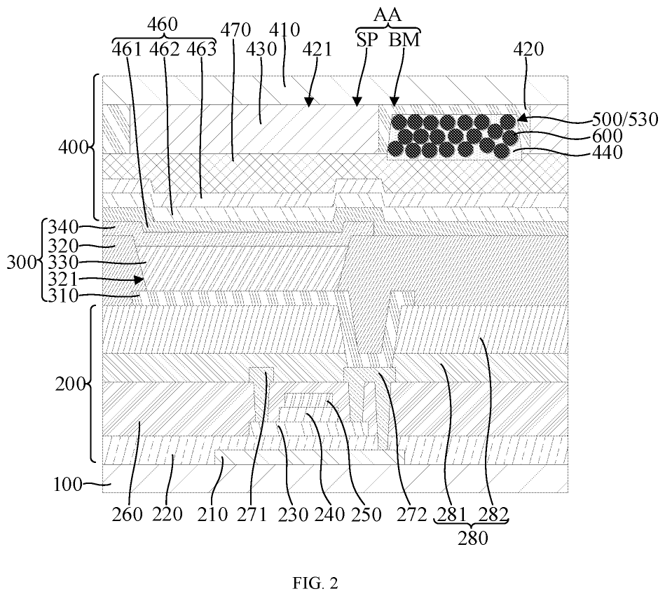

As shown in FIG. 2, the color filter unit 400 is provided with a buffer groove 500, and the buffer groove 500 of the color filter unit 400 is provided with a plurality of elastic particles 600. When the display device is subject to an impact, the plurality of elastic particles 600 in the buffer groove 500 are compressed and deformed after being pressed, so as to play a role of buffering and effectively improve the impact resistance of the display device. When the impact force is exhausted, the plurality of elastic particles 600 in the buffer groove 500 return to the initial state.

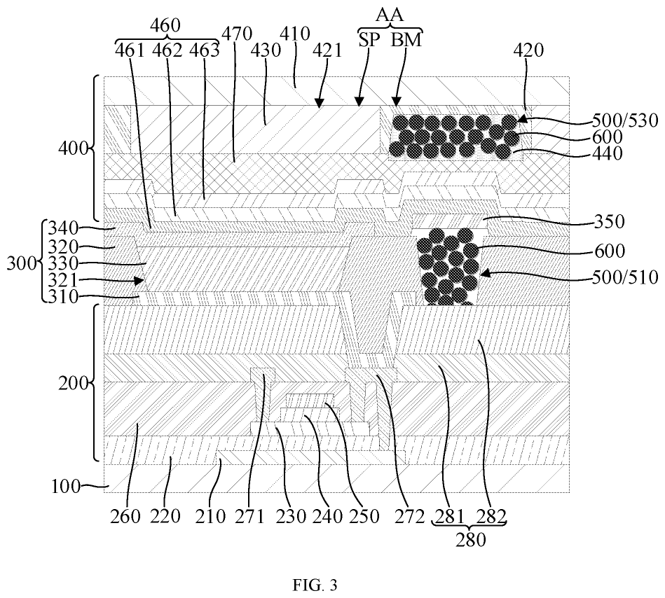

As shown in FIG. 3, both the light emitting device layer 300 and the color filter unit 400 are provided with buffer grooves 500, and both the buffer grooves 500 of the light emitting device layer 300 and the buffer grooves 500 of the color filter unit 400 are provided with a plurality of elastic particles 600. When the display device is subject to an impact, the plurality of elastic particles 600 in the buffer groove 500 are compressed and deformed after being pressed, so as to play a role of buffering and effectively improve the impact resistance of the display device. When the impact force is exhausted, the plurality of elastic particles 600 in the buffer groove 500 return to the initial state.

In the display device according to an embodiment of the present application, a buffer groove 500 is provided in at least one of the light emitting device layer 300 or the color filter unit 400, and a plurality of elastic particles 600 are filled in the buffer groove 500. When the display device is subject to an impact, the plurality of elastic particles 600 in the buffer groove 500 are compressed and deformed after being pressed, so as to play a role of buffering and effectively improve the impact resistance of the display device. When the impact force is exhausted, the plurality of elastic particles 600 in the buffer groove 500 return to the initial state.

Specifically, in the display device according to an embodiment of the present application, when the buffer groove 500 is fully filled with a plurality of elastic particles 600, since the space for compressing and deforming the elastic particles 600 is small, the buffering function of the elastic particles 600 may be greatly weakened. In order to ensure the buffering function of the elastic particles 600 by providing the sufficient space for compressing and deforming the elastic particles 600, the filling amount of the elastic particles 600 in the buffer groove 500 is less than 95%, that is, in the natural state, the volume occupied by the elastic particles 600 in the buffer groove 500 is less than 95% of the volume of the buffer groove 500. In this embodiment, the filling amount of the elastic particles 600 in the buffer groove 500 may be 94%, 90%, 85%, 80%, 75%, 70%, 65%, or 60%, etc., and the filling amount of the elastic particles 600 in the buffer groove 500 may be appropriately adjusted according to the actual selection and specific requirements.

Specifically, in the display device according to an embodiment of the present application, the display device has a display area AA, the display area AA includes a light shielding area BM and a plurality of sub-pixel areas SP, the light shielding area BM divides the display area AA into a plurality of sub-pixel areas SP, and the plurality of sub-pixel areas SP are arranged at intervals. Specifically, the plurality of sub-pixel areas SP may be arranged in an array. The buffer groove 500 and the plurality of elastic particles 600 filled in the buffer groove 500 are disposed corresponding to the light shielding area BM. In this configuration, the elastic particles 600 do not block normal light emitting of the display device.

Specifically, in the display device according to an embodiment of the present application, the light emitting device layer 300 includes a first electrode 310, a pixel defining layer 320, a light emitting function layer 330, and a second electrode 340, and the first electrode 310 is provided on the driving circuit layer 200. The pixel defining layer 320 covers the first electrode 310 and the driving circuit layer 200, the pixel defining layer 320 is defined with a pixel opening 321, the pixel opening 321 is defined corresponding to the sub-pixel area SP of the display area AA, and the pixel opening 321 exposes the first electrode 310; the light emitting function layer 330 is provided on the first electrode 310 in the pixel opening 321, and the second electrode 340 covers the light emitting function layer 330 and the pixel defining layer 320. In this configuration, by providing a voltage difference between the first electrode 310 and the second electrode 340, the light emitting function layer 330 may be actively caused to emit light, thereby realizing a display function.

Specifically, the light emitting device layer 300 includes a plurality of first electrodes 310, the first electrodes 310 are in one-to-one correspondence with the sub-pixel regions SP, the pixel defining layer 320 is provided with a plurality of pixel openings 321, each of the pixel openings 321 correspondingly expose one first electrode 310, a corresponding light emitting function layer 330 is deposited on the first electrode 310 in each pixel opening 321, and the second electrode 340 is disposed on the light emitting function layer 330 in each pixel opening 321. In this way, each first electrode 310 and its corresponding light emitting function layer 330 and the second electrode 340 together form an OLED device. In this embodiment, each second electrode 340 may correspond to one, two or more sub-pixel regions SPs, which are not particularly limited herein.

Specifically, the first electrode 310 and the second electrode 340 have opposite polarities, for example, when the first electrode 310 is an anode, the second electrode 340 is a cathode; when the first electrode 310 is a cathode, the second electrode 340 is an anode.

Specifically, the light emitting function layer 330 includes a hole injection layer, a hole transport layer, a light emitting layer, an ion transport layer, and an ion injection layer, which are stacked in this order from the anode toward the cathode, and the specific structure of the light-emitting function layer 330 may be appropriately modified according to the actual conditions and the specific requirements. For example, the light-emitting function layer 330 includes a hole injection transport layer, a light emitting layer, and an ion injection transport layer, which are stacked in this order from the anode toward the cathode, and it is not uniquely defined herein.

Specifically, as shown in FIGS. 1 and 3, the light emitting function layer 330 is provided with a buffer groove 500. Specifically, the buffer groove 500 includes a first buffer groove 510 disposed in the pixel defining layer 320, and a plurality of elastic particles 600 are provided in the first buffer groove 510. In this configuration, when the display device is subject to an impact, the plurality of elastic particles 600 in the first buffer groove 510 are compressed and deformed after being pressed, so as to play a role of buffering and effectively improve the impact resistance of the display device; when the impact force is exhausted, the plurality of elastic particles 600 in the first buffer groove 510 return to the initial state. In this embodiment, the first buffer groove 510 is provided with a plurality of layers of elastic particles 600, and the number of layers of elastic particles 600 in the first buffer groove 510 may be one layer, two layers, three layers, four layers or five layers. In this embodiment, in the first buffer groove 510, the filling amount of the elastic particles 600 is less than 95%.

Specifically, as shown in FIGS. 1 and 3, the display device further includes a first force-bearing layer 350 disposed on the pixel defining layer 320, the first force-bearing layer 350 is spaced apart from the second electrode 340, and the first force-bearing layer 350 covers the elastic particles 600 in the first buffer groove 510. In this configuration, when the display device is subject to an impact, an impact force is firstly applied to the first force-bearing layer 350, and the first force-bearing layer 350 may act as a buffer for dispersing the impact force; subsequently, the first force-bearing layer 350 transmits the impact force to the plurality of elastic particles 600 in the first buffer groove 510, the plurality of elastic particles 600 are compressed and deformed after being pressed, and the plurality of elastic particles 600 may act as a buffer, in this way, the impact resistance performance of the display device may be better improved. When the impact force is exhausted, the plurality of elastic particles 600 in the first buffer groove 510 return to the initial state. In this embodiment, the first force-bearing layer 350 is disposed corresponding to the light shielding area BM of the display area AA.

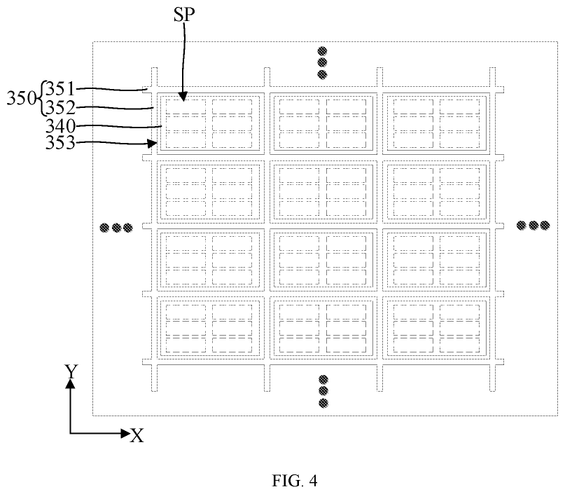

Specifically, in conjunction with FIG. 4, the first force-bearing layer 350 includes a plurality of first lines 351 extending in a first direction X and a plurality of second lines 352 extending in a second direction Y. The first line 351 intersects the second line 352, that is, the first direction X intersects the second direction Y, and the first buffer groove 510 is provided at the intersection between the first line 351 and the second line 352. In this configuration, when the display device is subject to an impact, an impact force is firstly applied to the intersection between the first and second lines 351 and 352, and at this time, a part of the impact force is dispersed along the first and second lines 351 and 352 from the intersection between the first and second lines 351 and 352, so that the first force-bearing layer 350 acts as a buffer; subsequently, the impact force is transmitted to the plurality of elastic particles 600 in the first buffer groove 510 from the intersection between the first line 351 and the second line 352, the plurality of elastic particles 600 are compressed and deformed after being pressed, and the plurality of elastic particles 600 may act as a buffer, in this way, the impact resistance of the display device may be better improved.

Specifically, the first direction X and the second direction Y are disposed perpendicular to each other. Of course, the first direction X and the second direction Y may be disposed at other angles according to the actual conditions and the specific requirements, so long as the intersection between the first direction X and the second direction Y is ensured, which is not uniquely defined herein.

Specifically, the first force-bearing layer 350 includes a plurality of first lines 351 and a plurality of second lines 352, the plurality of first lines 351 are sequentially arranged at intervals along the second direction Y, and the plurality of second lines 352 are sequentially arranged at intervals along the first direction X, so that the first force-bearing layer 350 is in a mesh. In this embodiment, the second electrode 340 is spaced apart from the first line 351, the second electrode 340 is spaced apart from the second line 352, the plurality of first lines 351 and the plurality of second lines 352 are combined to form a plurality of first mesh holes 353, and each of the second electrodes 340 is located in a corresponding first mesh hole 353.

Specifically, as shown in FIGS. 1, 2, 3, 5 and 6, the driving circuit layer 200 includes a light shielding electrode 210, a buffer layer 220, an active layer 230, a gate insulating layer 240, a gate 250, an interlayer dielectric layer 260, a source 271, a drain 272, and an interlayer insulating layer 280. The light shielding electrode 210 is disposed on the substrate 100, and the buffer layer 220 covers the substrate 100 and the light shielding electrode 210. The active layer 230 is disposed on the buffer layer 220 and corresponds to the light shielding electrode 210. The gate insulating layer 240 is disposed on the active layer 230, and the gate 250 is disposed on the gate insulating layer 240. The interlayer dielectric layer 260 covers the buffer layer 220, the active layer 230, and the gate 250. The source 271 and the drain 272 are spaced apart from each other on the interlayer dielectric layer 260. The source 271 is electrically connected to one end of the active layer 230, the drain 272 is electrically connected to the other end of the active layer 230, and the interlayer insulating layer 280 covers the interlayer dielectric layer 260, the source 271 and the drain 272. The first electrode 310 is electrically connected to the drain 272. It may be understood that the specific structure of the driving circuit layer 200 may be appropriately modified according to the actual selection and specific requirements, and it is not uniquely limited herein.

Specifically, the drain 272 is also electrically connected to the light shielding electrode 210. With this structure, the impedance of the lines may be reduced, the voltage drop of lines in the display device may be reduced, thereby improving the brightness uniformity of the display device and reducing the power consumption of the display device.

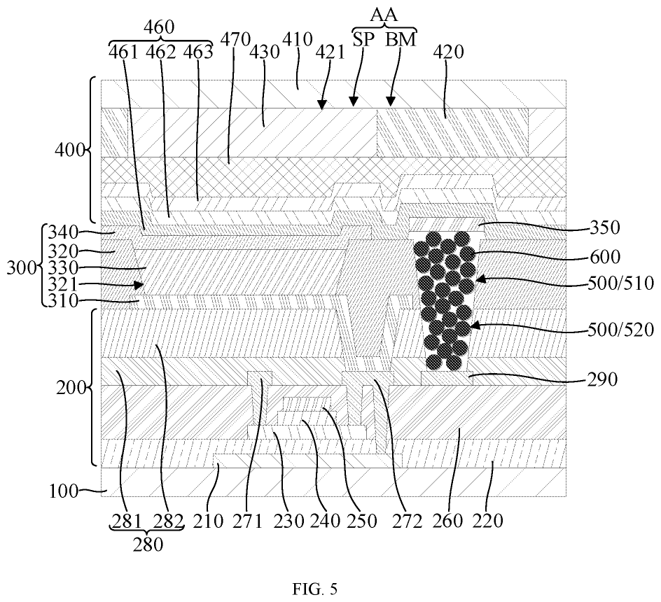

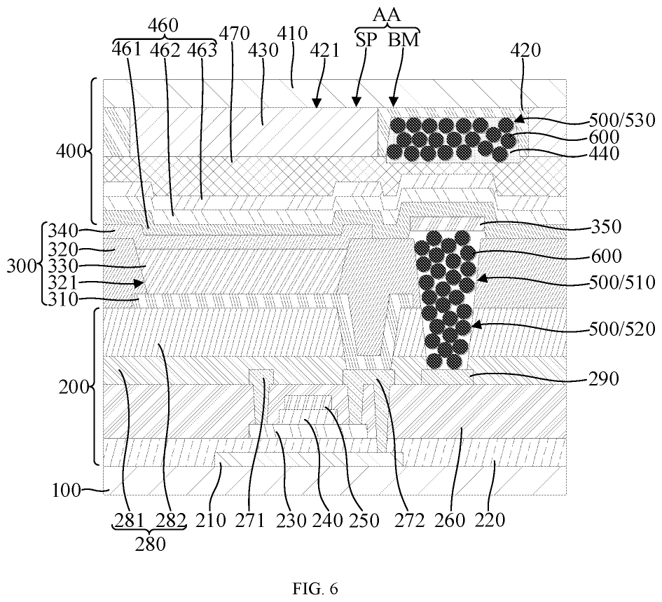

Specifically, as shown in FIGS. 5 and 6, the driving circuit layer 200 further includes a first touch electrode 290, and the first buffer groove 510 exposes the first touch electrode 290. Both the first force-bearing layer 350 and the elastic particles 600 have an electrical conductivity, and the first force-bearing layer 350 is electrically connected to the first touch electrode 290 through the elastic particles 600 in the first buffer groove 510. In this configuration, when the display device is pressed, the force is firstly applied to the first force-bearing layer 350, the first force-bearing layer 350 transmits the force to the plurality of elastic particles 600 in the first buffer groove 510, and the plurality of elastic particles 600 are compressed and deformed after being pressed, so that the contact area between the plurality of elastic particles 600 in the first buffer groove 510 and the first touch electrode 290 is increased, and the contact resistance between the plurality of elastic particles 600 in the first buffer groove 510 and the first touch electrode 290 is reduced. Thus, by detecting the change in the contact resistance between the plurality of elastic particles 600 in the first buffer groove 510 and the first touch electrode 290, the in-cell/on-cell touch sensing may be realized, and there is no need to add external touch device to the display device, which is benefit to reduce the thickness of the display device.

In the embodiments shown in FIGS. 5 and 6, the first touch electrode 290 is arranged on the same layer as the source 271 and the drain 272, so that the production process may be simplified. Of course, the first touch electrode 290 may be disposed on other layer structures according to the actual selection and specific requirements, for example, the first touch electrode 290 may be disposed on the same layer as the gate 250, or the first touch electrode 290 may be disposed on the same layer as the light shielding electrode 210, which is not uniquely defined herein.

It should be noted that the meaning of “arranging on the same layer” means that it is completed by one process, and the meaning of “arranging on the same layer” will not be repeatedly explained below.

Specifically, as shown in FIGS. 5 and 6, the first touch electrode 290 is disposed on the same layer as the source 271 and the drain 272, and the interlayer insulating layer 280 further covers the first touch electrode 290. The buffer groove 500 further includes a second buffer groove 520 disposed in the interlayer insulating layer 280, and the second buffer groove 520 exposes the first touch electrode 290. The second buffer groove 520 is provided corresponding to the first buffer groove 510, and a plurality of elastic particles 600 are provided in the second buffer groove 520. The first force-bearing layer 350 is electrically connected to the first touch electrode 290 through the elastic particles 600 in the first buffer groove 510 and the second buffer groove 520. In this embodiment, the interlayer insulating layer 280 includes a first insulating layer 281 and a second insulating layer 282. The first insulating layer 281 covers the interlayer dielectric layer 260, the source 271, the drain 272, and the first touch electrode 290, and the second insulating layer 282 covers the first insulating layer 281. Both the first insulating layer 281 and the second insulating layer 282 are provided with second buffer grooves 520. The second buffer grooves 520 of the first insulating layer 281 communicate with the second buffer grooves 520 of the second insulating layer 282, and the second buffer grooves 520 of the second insulating layer 282 communicate with the first buffer grooves 510. In this embodiment, the second buffer groove 520 is provided with a plurality of layers of elastic particles 600, and the number of layers of elastic particles 600 in the second buffer groove 520 may be one layer, two layers, three layers, four layers or five layers. In this embodiment, in the second buffer groove 520, the filling amount of the elastic particles 600 is less than 95%.

Specifically, as shown in FIGS. 2, 3, 6 and 7, the color filter unit 400 includes a package cover plate 410 and a light shielding layer 420. The light shielding layer 420 may be, but is not limited to, a black matrix. The light shielding layer 420 is disposed on a side of the package cover plate 410 near the light emitting device layer 300, and the light shielding layer 420 is disposed corresponding to the light shielding area BM. The buffer groove 500 includes a third buffer groove 530 disposed in the light shielding layer 420, and a plurality of elastic particles 600 are disposed in the third buffer groove 530. In this configuration, when the display device is subject to an impact, the plurality of elastic particles 600 in the third buffer groove 530 are compressed and deformed after being pressed, so as to play a role of buffering and effectively improve the impact resistance of the display device. When the impact force is exhausted, the plurality of elastic particles 600 in the buffer groove 500 return to the initial state. In this embodiment, in the third buffer groove 530, the filling amount of the elastic particles 600 is less than 95%.

Specifically, as shown in FIGS. 2, 3, 6, and 7, the display device further includes a second force-bearing layer 440 disposed on a side of the light shielding layer 420 near the light emitting device layer 300, and the second force-bearing layer 440 covers the elastic particles 600 in the third buffer groove 530. In this configuration, when the display device is subject to an impact, the second force-bearing layer 440 may act as a buffer for dispersing the impact force, and in this way, the impact resistance of the display device may be better improved.

Specifically, as shown in FIGS. 2, 3, 6 and 7, the material of the second force-bearing layer 440 is a polymer gel, and the polymer gel may be, in particular, a CNC DPC hydrogel, a CNC-C8 DPC hydrogel, or another polymer hydrogel. The polymer gel has good elastic and encapsulating properties, and may function as a buffer for dispersing impact force. The polymer gel fills the gaps between adjacent elastic particles 600 in the third buffer groove 530. In this embodiment, the polymer gel may be doped with the water absorbing agent, or the elastic particles 600 in the third buffer groove 530 may be injected with the water absorbing agent, thereby improving the sealing property of the display device.

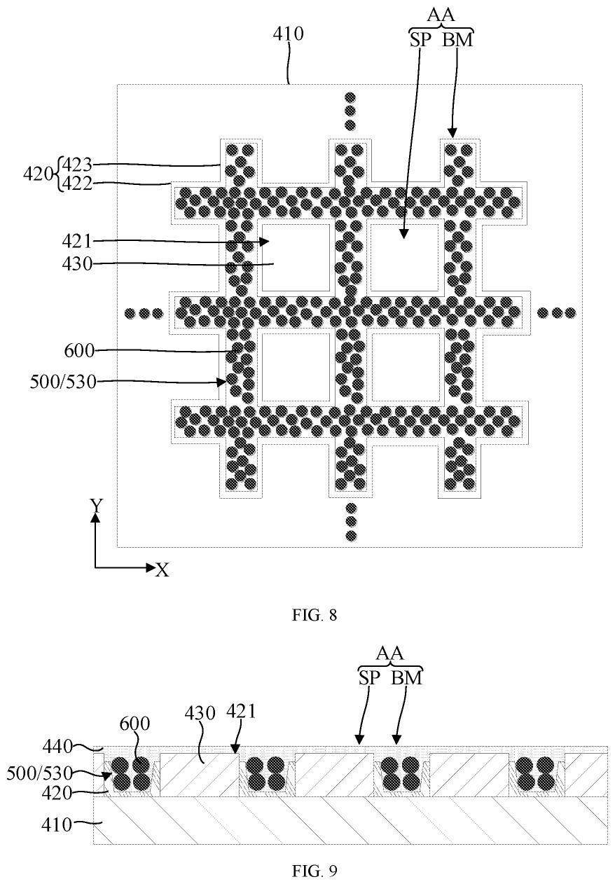

Specifically, as shown in FIG. 8, the light shielding layer 420 includes a first light shielding strip 422 extending in a first direction X and a second light shielding strip 423 extending in a second direction Y. The first light shielding strip 422 intersects the second light shielding strip 423, that is, the first direction X intersects the second direction Y. Each of the first light shielding strip 422 and the second light shielding strip 423 is provided with a third buffer groove 530, and each of the third buffer groove 530 of the first light shielding strip 422 and the third buffer groove 530 of the second light shielding strip 423 is provided with a plurality of elastic particles 600.

Specifically, the light shielding layer 420 encloses a plurality of grooves 421 on the package substrate 100, and each groove 421 is filled with a color filter 430. The color filter 430 may include a red color filter 430, a green color filter 430, and a blue color filter 430. In this configuration, the light emitted by the light emitting function layer 330 is emitted after passing through the color filter 430, and thus the contrast of the display device may be improved. In this embodiment, the light shielding layer 420 includes the plurality of first light shielding strips 422 and the plurality of second light shielding strips 423, the plurality of first light shielding strips 422 are sequentially arranged at intervals along the second direction Y, and the plurality of second light shielding strips 423 are sequentially arranged at intervals along the first direction X, so that the plurality of first light shielding strips 422 and the plurality of second light shielding strips 423 are combined to form a plurality of grooves 421, each of which is provided with a corresponding color filter 430.

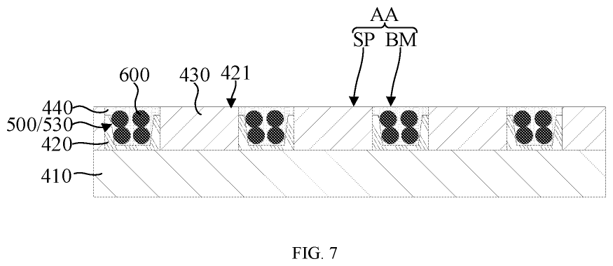

Specifically, when the material of the second force-bearing layer 440 is a polymer gel, as shown in FIG. 7, the polymer gel may cover only the light shielding layer 420 and the elastic particles 600 in the third buffer groove 530; of course, the polymer gel may also be provided as shown in FIG. 9, and the polymer gel may completely cover the light shielding layer 420, the color filter 430, and the elastic particles 600 in the third buffer groove 530. Both of the above embodiments may achieve the buffering effect, and it is not particularly limited herein. In this embodiment, the third buffer groove 530 is provided with a plurality of layers of elastic particles 600, and the number of layers of elastic particles 600 in the third buffer groove 530 may be one layer, two layers, three layers, four layers or five layers.

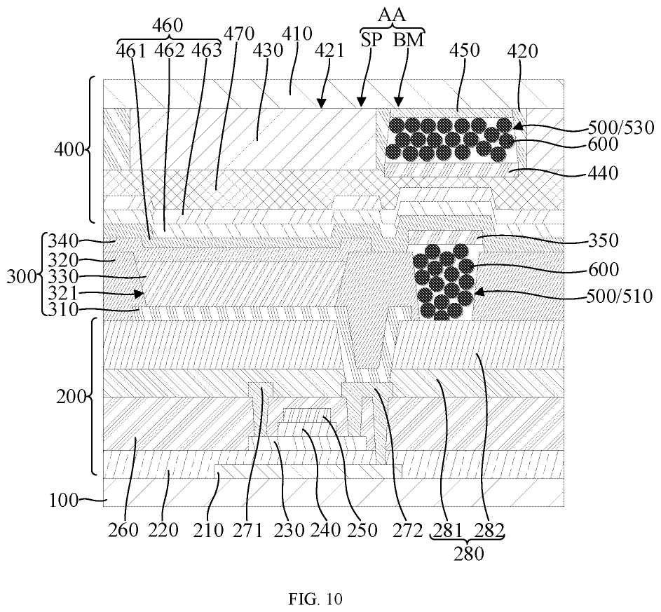

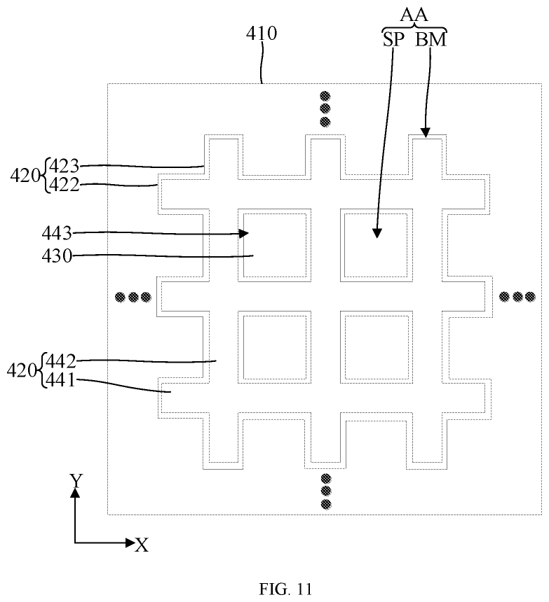

Specifically, as shown in FIGS. 5 and 6, the driving circuit layer 200 is provided with a first touch electrode 290. Of course, the touch electrode may be integrated on the package cover plate 410 according to the actual selection and specific requirements. As shown in FIGS. 10 and 11, the material of the second force-bearing layer 440 is not a polymer gel, and the display device further includes a second touch electrode 450 disposed between the package cover plate 410 and the light shielding layer 420, and the third buffer groove 530 exposes the second touch electrode 450; both the second force-bearing layer 440 and the elastic particles 600 have conductive properties, and the second force-bearing layer 440 is electrically connected to the second touch electrode 450 through the elastic particles 600 in the third buffer groove 530. In this embodiment, the second force-bearing layer 440 is disposed corresponding to the light-shielding area BM of the display area AA. In this configuration, when the display device is pressed, the force is firstly applied to the second force-bearing layer 440, the second force-bearing layer 440 transmits the force to the plurality of elastic particles 600 in the third buffer groove 530, and the plurality of elastic particles 600 are compressed and deformed after being pressed, so that the contact area between the plurality of elastic particles 600 in the third buffer groove 530 and the second touch electrode 450 is increased, and the contact resistance between the plurality of elastic particles 600 in the third buffer groove 530 and the second touch electrode 450 is reduced. In this way, by detecting the change in the contact resistance between the plurality of elastic particles 600 in the third buffer groove 530 and the second touch electrode 450, the in-cell/on-cell touch sensing may be realized, and there is no need to add external touch device to the display device, which is benefit to reduce the thickness of the display device.

In particular, in conjunction with FIGS. 10 and 11, the second force-bearing layer 440 includes a plurality of third lines 441 extending in a first direction X and a plurality of fourth lines 442 extending in a second direction Y. The third line 441 intersects the fourth line 442, i.e., the first direction X intersects the second direction Y. In this configuration, when the display device is subject to an impact, an impact force is firstly applied to the third and fourth lines 441 and 442, and at this time, a part of the impact force is dispersed along the third and fourth lines 441 and 442 from the intersection between the third and fourth lines 441 and 442, so that the second force-bearing layer 440 functions as a buffer; subsequently, the impact force is transmitted from the third and fourth lines 441 and 442 to the plurality of elastic particles 600 in the third buffer groove 530, and the plurality of elastic particles 600 are compressed and deformed after being pressed, so that the plurality of elastic particles 600 may act as a buffer. In this way, the impact resistance of the display device may be better improved. In this embodiment, the second touch electrode 450 is provided corresponding to the intersection between the third line 441 and the fourth line 442.

Specifically, in conjunction with FIGS. 10 and 11, the second force-bearing layer 440 includes a plurality of third lines 441 and a plurality of fourth lines 442. The plurality of third lines 441 are sequentially arranged at intervals along the second direction Y, and the plurality of fourth lines 442 are sequentially arranged at intervals along the first direction X, so that the second force-bearing layer 440 is in a mesh. In this embodiment, the plurality of third lines 441 and the plurality of fourth lines 442 are combined to form a plurality of second mesh holes 443, each of which is provided with a corresponding color filter 430.

Specifically, the display device further includes an encapsulation layer 460 and a bonding adhesive 470. The encapsulation layer 460 covers the light emitting device layer 300 and the first force-bearing layer 350. The encapsulation layer 460 and the bonding adhesive 470 are located on the side of the color filter unit 400 near the light emitting device layer 300. The bonding adhesive 470 is disposed on the side of the encapsulation layer 460 near the light shielding layer 420. The bonding adhesive 470 adheres the light shielding layer 420, the color filter 430, and the second force-bearing layer 440 to the encapsulation layer 460. In this embodiment, the encapsulation layer 460 includes a first inorganic layer 461, an organic layer 462, and a second inorganic layer 463, the first inorganic layer 461 covers the light emitting device layer 300 and the first force-bearing layer 350, the organic layer 462 covers the first inorganic layer 461, and the second inorganic layer 463 covers the organic layer 462.

Specifically, in the display device according to the embodiment of the present application, the elastic particles 600 are selected from at least one of silver nanoparticles, zinc oxide particles, tin oxide particles, titanium dioxide particles, gold particles, aluminum particles, or carbon nanotube particles. Of course, the material of the elastic particles 600 may be appropriately changed according to actual conditions and specific requirements. In this embodiment, the surface of the elastic particles 600 is modified with hydrophobic and/or oleophobic functional groups, for example, the surface of the elastic particles 600 is modified with fluorine ion functional groups, and in this way, the elastic particles 600 are not easily eroded by the moisture, and the reliability of the display device may be improved.

Specifically, the particle size of the elastic particles 600 ranges from 5 nanometers to 100 nanometers, for example, the particle size of the elastic particles 600 is 5 nanometers, 10 nanometers, 20 nanometers, 30 nanometers, 40 nanometers, 50 nanometers, 60 nanometers, 70 nanometers, 80 nanometers, 90 nanometers, or 100 nanometers, and the particle size of the elastic particles 600 may be appropriately modified according to the actual selection and specific requirements.

The display device provided in the embodiments of the present application is described in detail above. The principles and implementations of the present application are described in detail here with specific examples. The above description of the embodiments is merely intended to help understand the method and core ideas of the present application. At the same time, a person skilled in the art may make changes in the specific embodiments and application scope according to the idea of the present application. In conclusion, the content of the present specification should not be construed as a limitation to the present application.

What is claimed is:

1. A display device comprising:
a substrate;
a driving circuit layer disposed on the substrate;
a light emitting device layer disposed on the driving circuit layer, wherein the light emitting device layer is electrically connected to the driving circuit layer; and
a color filter unit covering the light emitting device layer,
wherein at least one of the light emitting device layer or the color filter unit is provided with a buffer groove, a plurality of elastic particles are provided in the buffer groove.

2. The display device according to claim 1, wherein a filling amount of the elastic particles in the buffer groove is less than 95%.

3. The display device according to claim 1, wherein the display device comprises a display area, the display area comprises a light shielding area and a plurality of sub-pixel areas, the light shielding area divides the display area into the plurality of sub-pixel areas, and both the buffer groove and the plurality of elastic particles are disposed corresponding to the light shielding area.

4. The display device according to claim 1, wherein the driving circuit layer comprises a light shielding electrode, a buffer layer, an active layer, a gate insulating layer, a gate, an interlayer dielectric layer, a source, a drain and an interlayer insulating layer, wherein the light shielding electrode is disposed on the substrate, the buffer layer covers the substrate and the light shielding electrode, the active layer is disposed on the buffer layer and corresponds to the light shielding electrode, the gate insulating layer is disposed on the active layer, the gate is disposed on the gate insulating layer, the interlayer dielectric layer covers the buffer layer, the active layer and the gate, the source and the drain are spaced apart from each other on the interlayer dielectric layer, the source is electrically connected to one end of the active layer, the drain is electrically connected to another end of the active layer, and the interlayer insulating layer covers the interlayer dielectric layer, the source and the drain.

5. The display device according to claim 1, wherein the light emitting device layer comprises a first electrode, a pixel defining layer, a light emitting function layer, and a second electrode, the first electrode is provided on the driving circuit layer;
the pixel defining layer covers the first electrode and the driving circuit layer, the pixel defining layer is provided with a pixel opening, and the pixel opening exposes the first electrode;
the light emitting function layer is disposed on the first electrode in the pixel opening;
the second electrode covers the light emitting function layer and the pixel defining layer; and
the buffer groove comprises a first buffer groove disposed in the pixel defining layer, and the plurality of elastic particles are disposed in the first buffer groove.

6. The display device according to claim 5, wherein the display device further comprises a first force-bearing layer disposed on the pixel defining layer, the first force-bearing layer is spaced apart from the second electrode, and the first force-bearing layer covers the elastic particles in the first buffer groove.

7. The display device according to claim 6, wherein the display device further comprises an encapsulation layer, the encapsulation layer covers the light emitting device layer and the first force-bearing layer, and the encapsulation layer is located on a side of the color filter unit near the light emitting device layer.

8. The display device according to claim 7, wherein the encapsulation layer comprises a first inorganic layer, an organic layer, and a second inorganic layer, the first inorganic layer covers the light emitting device layer and the first force-bearing layer, the organic layer covers the first inorganic layer, and the second inorganic layer covers the organic layer.

9. The display device according to claim 6, wherein the first force-bearing layer comprises a plurality of first lines extending in a first direction and a plurality of second lines extending in a second direction, the first lines intersect the second lines, and the first buffer groove is disposed corresponding to intersections between the first lines and the second lines.

10. The display device according to claim 6, wherein the driving circuit layer comprises a first touch electrode, and the first buffer groove exposes the first touch electrode;
both the first force-bearing layer and the elastic particles have an electrical conductivity, and the first force-bearing layer is electrically connected to the first touch electrode through the elastic particles in the first buffer groove.

11. The display device according to claim 10, wherein the driving circuit layer further comprises an interlayer insulating layer covering the first touch electrode;
the buffer groove further comprises a second buffer groove provided in the interlayer insulating layer, and the second buffer groove exposes the first touch electrode;
the second buffer groove is disposed corresponding to the first buffer groove, and a plurality of the elastic particles are disposed in the second buffer groove; and
the first force-bearing layer is electrically connected to the first touch electrode through the elastic particles in the first buffer groove and the elastic particles in the second buffer groove.

12. The display device according to claim 11, wherein the interlayer insulating layer comprises a first insulating layer and a second insulating layer, and wherein the first insulating layer covers the first touch electrode, the second insulating layer covers the first insulating layer, each of the first insulating layer and the second insulating layer is provided with the second buffer groove, the second buffer groove of the first insulating layer communicates with the second buffer groove of the second insulating layer, and the second buffer groove of the second insulating layer communicates with the first buffer groove.

13. The display device according to claim 1, wherein the color filter unit comprises a package cover plate and a light shielding layer, the light shielding layer is disposed on a side of the package cover plate near the light emitting device layer, the buffer groove comprises a third buffer groove disposed on the light shielding layer, and the plurality of elastic particles are disposed in the third buffer groove.

14. The display device according to claim 13, wherein the light shielding layer comprises a first light shielding strip extending in a first direction and a second light shielding strip extending in a second direction, the first light shielding strip intersects the second light shielding strip, and each of the first light shielding strip and the second light shielding strip is provided with the third buffer groove.

15. The display device according to claim 14, wherein a plurality of first light shielding strips and a plurality of second light shielding strips are combined to form a plurality of grooves, and a corresponding color filter is provided in each of the plurality of grooves.

16. The display device according to claim 13, wherein the display device further comprises a second force-bearing layer disposed on a side of the light shielding layer near the light emitting device layer, the second force-bearing layer covers the elastic particles in the third buffer groove.

17. The display device according to claim 16, wherein a material of the second force-bearing layer is a polymer gel, and the polymer gel fills gaps between the adjacent elastic particles in the third buffer groove.

18. The display device according to claim 16, wherein the display device further comprises a second touch electrode disposed between the package cover plate and the light shielding layer, and the third buffer groove exposes the second touch electrode; and
both the second force-bearing layer and the elastic particles have an electrical conductivity, and the second force-bearing layer is electrically connected to the second touch electrode through the elastic particles in the third buffer groove.

19. The display device according to claim 1, wherein the elastic particles are selected from at least one of silver nanoparticles, zinc oxide particles, tin oxide particles, titanium dioxide particles, gold particles, aluminum particles, or carbon nanotube particles.

20. The display device according to claim 1, wherein a particle size of the elastic particles ranges from 5 nanometers to 100 nanometers.
